(19) United States
(12) Patent Application Publication
(10) Pub. No.: US 2020/0091397 A1
(43) Pub. Date: Mar. 19, 2020

(54) MGB2 SUPERCONDUCTIVE THIN FILM WIRE MATERIAL AND PRODUCTION METHOD THEREFOR

(71) Applicant: HITACHI, LTD., Tokyo (JP)

(72) Inventors: Takumu IWANAKA, Tokyo (JP); Hiroshi KOTAKI, Tokyo (JP); Toshiaki KUSUNOKI, Tokyo (JP)

(73) Assignee: HITACHI, LTD., Tokyo (JP)

(21) Appl. No.: 16/609,476

(22) PCT Filed: Mar. 7, 2018
(86) PCT No.: PCT/JP2018/008846

§ 371 Date: Oct. 30, 2019

(30) Foreign Application Priority Data
May 9, 2017 (JP) 2017-093226

(51) Int. Cl. H01L 39/12; H01L 39/24; H01B 12/06; C01B 35/04

(52) U.S. Cl. CPC H01L 39/12; H01L 39/2487; H01B 12/06; C01P 2006/40; C01P 2004/04; C01P 2002/01; C01P 2004/24; C01B 35/04

(57) ABSTRACT

Provided is an MgB₂ superconductive thin film wire material allowing for lower costs while maintaining superconductive properties that are equal to or greater than those of the MgB₂ superconductive thin film wire material of prior art, and to provide a production method for the superconductive thin film wire material. The MgB₂ superconductive thin film wire material according to the present invention is a superconductive wire material comprising an MgB₂ thin film formed over an elongated metal base material, characterized in that the MgB₂ thin film exhibits a critical temperature of 30 K or higher, and has a microscopic organization wherein MgB₂ columnar crystal grains stand densely packed on the surface of the elongated metal base material, and a layer of Mg oxide is formed in such a manner as to surround the MgB₂ columnar crystal grains in the grain boundary regions of the MgB₂ columnar crystal grains.

### TECHNICAL FIELD

The present invention relates to an MgB₂ (magnesium diboride) superconductive wire material, and more particularly to an MgB₂ superconductive thin film wire material using an MgB₂ thin film as a superconductive conductor and a production method therefor.

### BACKGROUND ART

An MgB₂ superconductor has a high critical temperature (T_{c}=39 K) as a metal superconductor, and is expected as a superconductive material that can achieve a superconductive electromagnet providing liquid helium free operation (for example, at temperatures of 10 to 20 K). In particular, 20 K cooling is performed in a temperature range that allows cooling using liquid hydrogen, and is also expected to be achieved in the future in cooperation with a hydrogen infrastructure (for example, a hydrogen station and the like).

By applying the MgB₂ superconductor to a superconductive electromagnet of a superconductive magnetic system (for example, a nuclear magnetic resonance (NMR) apparatus, a magnetic resonance imaging (MRI) apparatus, a magnetically-suspended railway (Maglev Railway)) operated at 4.2 K, a temperature margin (difference between the critical temperature and the operating temperature) can be made larger than before, whereby quenching is less likely occur, which makes it possible to achieve a superconductive magnetic system having high thermal stability.

The superconductive wire material for constituting the superconductive electromagnet is required to be a long wire (for example, a length of 1 km or more) and to have a high current density that can be maintained even under a high magnetic field environment (for example, an environment of 5 T) generated by the superconductive magnet itself. From these viewpoints, the MgB₂ superconductor itself is a relatively new material, and is still under development, whereby various research and development of the MgB₂ superconductive wire material are carried out from the aspects of both a production method for a long wire and improvement in superconductive properties.

Conventionally, research and development of the MgB₂ superconductive wire material have mainly focused on a superconductive wire material produced by a powder-in-tube method on the premise of producing a long wire. The powder-in-tube (PIT) method includes the steps of: filling a metal pipe with a raw material powder (a mixed powder of an Mg (magnesium) powder and a B (boron) powder, or an MgB₂ powder, or a mixed powder additionally containing a third element added to those powders); applying drawing to the metal pipe filled with the powder to form a wire; and applying a thermal treatment (usually, 600° C. or higher) to produce and sinter a superconductive phase. The PIT method is advantageous for producing a long wire, but an MgB₂ superconductive wire material produced by the PIT method generally has disadvantages from the viewpoint of superconductive properties (for example, critical current density properties).

Meanwhile, examples of methods for producing superconductive devices including Josephson devices include a method utilizing a vacuum process (also referred to as a thin film process). An MgB₂ superconductive thin film produced by the vacuum process is advantageous in that it exhibits critical current density (J_{c}) properties that are one digit higher in a 4.2 K magnetic field than the MgB₂ superconductive wire material produced by the PIT method. Conventionally, the vacuum process has disadvantageously made it difficult to produce a long wire. However, recent progress of a long wire producing technique that applies a vacuum process to an oxide superconductor has raised expectation for achieving a thin film long wire having high J_{c} properties in the MgB₂ superconductor.

In order to improve the superconductive properties of the MgB₂ superconductor (for example, J_{c} properties in a high magnetic field), refinement of MgB₂ phase crystal grains (in other words, increase in a grain boundary density) and dispersion precipitation of non-superconductive phase fine particles effectively increase the density of a magnetic flux pinning center. Various techniques have been reported for improving the superconductive properties.

For example, PTL 1 (WO 2016/084513) describes “an MgB₂ superconductive thin film wire material including a long substrate and an MgB₂ thin film formed on the long substrate, wherein: the MgB₂ thin film has a microscopic organization in which MgB₂ columnar crystal grains densely stand on a surface of the long substrate, and has a critical temperature of 30 K or higher; in a grain boundary region of the MgB₂ columnar crystal grains, a predetermined transition metal element is dispersed and segregated; and the predetermined transition metal element is an element having a body-centered cubic lattice structure.

### CITATION LIST

### Patent Literature

PTL 1: WO2016/084513

### SUMMARY OF INVENTION

### Technical Problem

As described in PTL 1, by selectively diffusing the predetermined transition metal element into the grain boundary region of the MgB₂ columnar crystal grains, the MgB₂ superconductive thin film wire material exhibiting good J_{c} properties even in a 20 K magnetic field can be obtained. In order to diffuse the predetermined transition metal element into the grain boundary region of the MgB₂ columnar crystal grains, the production method includes a transition metal element layer forming step of forming a transition metal element layer between the surface of the MgB₂ thin film and/or the long substrate and the MgB₂ thin film, and a transition metal element diffusion heat treatment step of diffusing the transition metal element as essential steps.

Superconductive products such as superconductive wire materials and superconductive electromagnets are still expensive, and the cost reduction of the superconductive products is one of the most important issues in order to expand the utilization of the superconductive products. Meanwhile, the production method for the MgB₂ superconductive thin film wire material is apt to disadvantageously cause an increased total cost as the number of steps increases since the method has a relatively high process cost of each step utilizing the vacuum process.

Therefore, it is an object of the present invention to provide an MgB₂ superconductive thin film wire material allowing for lower costs than those of a conventional MgB₂ superconductive thin film wire material while maintaining superconductive properties equal to or greater than those of the conventional MgB₂ superconductive thin film wire material (for example, exhibiting good J_{c} properties even in a 20 K magnetic field), and a production method for the superconductive thin film wire material.

### Solution to Problem

(I) In order to achieve the above object, one aspect of the present invention is an MgB₂ superconductive thin film wire material including: a long metal substrate; and an MgB₂ thin film formed on the long metal substrate, wherein:

the MgB₂ thin film has a critical temperature of 30 K or higher, and has a microscopic organization in which MgB₂ columnar crystal grains densely stand on a surface of the long metal substrate, and an Mg oxide layer is formed in such a manner as to surround the MgB₂ columnar crystal grains in a grain boundary region of the MgB₂ columnar crystal grains.

In the present invention, the MgB₂ superconductive thin film wire material (I) can be improved and modified as follows.

(i) The Mg oxide layer has an average thickness of 1 nm or more and less than 7 nm.

(ii) A total area ratio of the Mg oxide layer in a plane parallel to a surface of the MgB₂ thin film is 2% or more and 20% or less.

(iii) The MgB₂ columnar crystal grains on a surface of the MgB₂ thin film have an average particle diameter of 25 nm or more and 250 nm or less.

(iv) The MgB₂ thin film has a thickness of 1 μm or more and 20 μm or less.

(v) The MgB₂ superconductive thin film wire material further includes a metal coating layer formed on a surface of the MgB₂ thin film.

(vi) The metal coating layer includes a layer made of Cr or Ni.

(II) In order to achieve the above object, another aspect of the present invention is a production method for an MgB₂ superconductive thin film wire material,

the MgB₂ superconductive thin film wire material including: a long metal substrate; and an MgB₂ thin film formed on the long metal substrate, wherein:

the MgB₂ thin film has a critical temperature of 30 K or higher, and has a microscopic organization in which MgB₂ columnar crystal grains densely stand on a surface of the long metal substrate and an Mg oxide layer is formed in such a manner as to surround the MgB₂ columnar crystal grains in a grain boundary region of the MgB₂ columnar crystal grains,

the method includes an MgB₂ thin film forming step of forming the MgB₂ thin film on the long metal substrate by a co-evaporation method under a predetermined temperature condition in a predetermined vacuum atmosphere;

the predetermined vacuum atmosphere is controlled so as to contain a highly oxidative gas in a partial pressure range of 0.05% or more and 0.2% or less of an Mg vapor partial pressure during deposition; and

in the predetermined temperature condition, a temperature of the long metal substrate is controlled to 250° C. or higher and 300° C. or lower.

The highly oxidative gas in the present invention refers to a gas having a stronger oxidizing power than that of an O₂ (oxygen) gas alone.

The present invention can be improved and modified as follows in the production method for an MgB₂ superconductive thin film wire material (II).

(vii) The highly oxidative gas is one or more of water vapor, ozone, and hydrogen peroxide.

(viii) A partial pressure of the highly oxidative gas is 5×10⁻⁷ Pa or more and 2×10⁻⁵ Pa or less.

(ix) The method further includes a metal coating layer forming step of further forming a metal coating layer on a surface of the MgB₂ thin film after the MgB₂ thin film forming step.

(x) The metal coating layer includes a layer made of Cr or Ni.

### Advantageous Effects of Invention

The present invention makes it possible to provide an MgB₂ superconductive thin film wire material allowing for lower costs than those of a conventional MgB₂ superconductive thin film wire material while maintaining superconductive properties equal to or greater than those of the conventional MgB₂ superconductive thin film wire material, and a production method for the superconductive thin film wire material.

### BRIEF DESCRIPTION OF DRAWINGS

FIG. 1 is a schematic view showing a configuration example of a deposition apparatus of an MgB₂ superconductive thin film wire material according to the present invention.

FIG. 2A is an annular dark field (ADF) image of a scanning transmission electron microscope (STEM) observation showing an example of a microscopic organization of a cross section of an MgB₂ thin film (film thickness: 5 μm) (a cross section perpendicular to the surface of the MgB₂ thin film).

FIG. 2B is a combination of Mg element mapping and O element mapping in FIG. 2A.

FIG. 2C is a schematic cross-sectional view of the MgB₂ thin film based on FIGS. 2A and 2B.

FIG. 3 is a transmission electron microscope (TEM) observation image showing an example of a microscopic organization of a horizontal cross section of an MgB₂ thin film (film thickness: 5 μm) (a cross section parallel to the surface of the MgB₂ thin film).

FIG. 4 is a schematic view showing an example of a microscopic organization of a cross section of an MgB₂ superconductive thin film wire material after a metal coating layer forming step.

FIG. 5 is a graph showing an example of the relationship between a critical current density J_{c} and an external magnetic field B in a temperature environment of 20 K in MgB₂ superconductive thin film wire materials of Example 1, Comparative Example 1, and Conventional Example 1.

### DESCRIPTION OF EMBODIMENTS

### Initial Consideration and Basic Concept of Present Invention

The present inventors have repeated research on an MgB₂ superconductive thin film wire material that can be produced at a lower cost than that of a conventional MgB₂ superconductive thin film wire material while maintaining superconductive properties equal to or greater than those of the conventional MgB₂ superconductive thin film wire material. In the research, an Mg oxide layer has been considered to be simultaneously produced in an MgB₂ thin film forming step in which a transition metal element dispersed and segregated in a grain boundary region of MgB₂ columnar crystal grains in a technique of PTL 1 is replaced with Mg oxide, and an MgB₂ thin film is formed on a long metal substrate.

First, except for intentionally introducing an O₂ gas into an MgB₂ film formation atmosphere, an MgB₂ thin film has been formed according to a film formation method described in PTL 1, and the influence of the MgB₂ thin film on a microscopic organization and superconductive properties has been investigated and examined. However, when the amount of O₂ (accurately, an O₂ gas partial pressure) set by back calculation from the amount of an Mg oxide to be produced has been introduced, the supposed amount of the Mg oxide has not been produced, and superconductive properties as expected have not been obtained.

Therefore, when an MgB₂ film has been formed while an O₂ gas partial pressure in an atmosphere or a substrate temperature (also referred to as a film formation temperature) has been changed, the production amount of the Mg oxide has been dramatically increased after a certain condition (the production amount of an MgB₂ phase has been dramatically decreased), which has caused largely deteriorated superconductive properties. From these experimental results, it has been found that the method for introducing the O₂ gas into the MgB₂ film formation atmosphere has extremely poor controllability of the production of the Mg oxide.

The present inventors have examined the factors of the experimental results in detail, and have considered as follows. From the experimental results that the amount of the Mg oxide supposed from the O₂ gas partial pressure introduced into the film formation atmosphere has not been produced, and the experimental results that the production amount of the Mg oxide has been dramatically increased after a certain condition, an oxidation reaction provided by introducing the O₂ gas (particularly, a dilute O₂ gas) has been considered to have a relatively high activation barrier. In other words, the oxidizing power of the dilute O₂ gas has been considered to be not as high as originally expected.

Therefore, the following hypothesis has been made. When an oxidizing gas having a lower activation barrier for the oxidation reaction than that of the dilute O₂ gas (a highly oxidative gas that causes a sufficient oxidation reaction even in a more dilute state than that of the O₂ gas) is introduced, the controllability of the production of the Mg oxide may be improved.

In order to confirm the hypothesis, a highly oxidative gas (for example, an active oxygen gas such as an ozone gas or a hydrogen peroxide gas, and water vapor) that is considered to have a higher oxidizing power than that of the dilute O₂ gas has been introduced into a film formation atmosphere to form an MgB₂ thin film. The influence of the MgB₂ thin film on a microscopic organization and superconductive properties has been considered. As a result, the controllability of the production of the Mg oxide has been confirmed to be improved to provide good superconductive properties. The present invention has been completed based on this finding.

Hereinafter, embodiments according to the present invention will be described according to a producing procedure with reference to the drawings. However, the present invention is not limited to the embodiments described below, and can be appropriately combined with or improved based on known techniques without departing from the technical concept of the invention. The same sign is provided for the same member and portion, and description of overlap will be omitted.

### Production Method for MgB₂ Superconductive Thin Film Wire Material

### Producing Apparatus

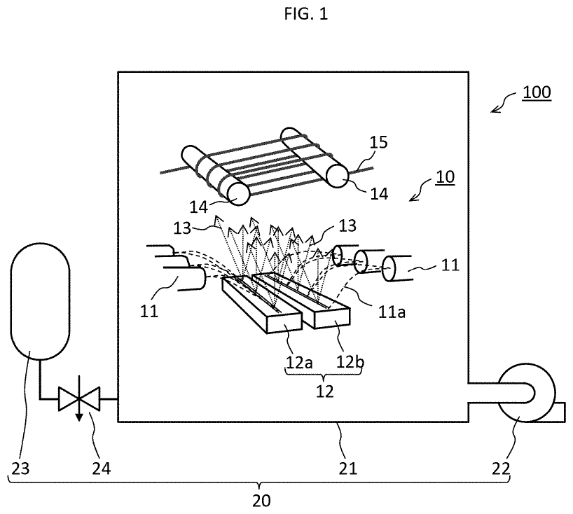

FIG. 1 is a schematic view showing a configuration example of a producing apparatus for an MgB₂ superconductive thin film wire material according to the present invention. FIG. 1 shows an example utilizing an electron beam heating co-evaporation method. Broadly speaking, a producing apparatus 100 shown in FIG. 1 includes an MgB₂ thin film forming mechanism 10 that forms an MgB₂ thin film and an atmosphere controlling mechanism 20 that controls an atmosphere during film formation.

The MgB₂ thin film forming mechanism 10 deflects and accelerates electron beams 11a emitted from an electron gun array 11, and irradiates the electron beams onto two linear-type raw material evaporation sources 12 (Mg evaporation source 12a, B evaporation source 12b). Then, raw material vapor 13 evaporated by heating is co-deposited on a tape-like long metal substrate 15 wound around a reel 14 more than once. The long metal substrate 15 is heated by a heater, not shown, (for example, a heater built in the reel 14 or a heater heating the long metal substrate 15 from behind) to a predetermined temperature. Mg atoms and B atoms that have reached the long metal substrate 15 chemically combine to form an MgB₂ thin film.

The atmosphere controlling mechanism 20 includes a vacuum chamber 21 that accommodates the MgB₂ thin film forming mechanism 10 therein, a pump 22 that subjects the inside of the vacuum chamber 21 to vacuum evacuation, a tank 23 that stores a highly oxidative gas introduced into the vacuum chamber 21, and a variable leak valve 24 that adjusts the introduction amount of the highly oxidative gas. The variable leak valve 24 is a valve capable of adjusting a flow rate from an extremely minute flow rate region, and the production of an Mg oxide in the MgB₂ thin film can be controlled by adjusting the introduction amount of the highly oxidative gas.

The producing apparatus for the MgB₂ superconductive thin film wire material according to the present invention may further include a metal coating layer forming mechanism (not shown) for forming a metal coating layer on the surface of the MgB₂ thin film in addition to the above configuration. The metal coating layer forming mechanism may be accommodated in a separate vacuum chamber and connected to the vacuum chamber 21 of the atmosphere controlling mechanism 20.

In the above, an example in the case of the electron beam heating co-evaporation method is shown as an MgB₂ thin film formation method, but the production method of the present invention is not limited thereto. Other known co-evaporation methods (for example, a heater heating co-evaporation method) may be utilized as long as a desired MgB₂ thin film is obtained. The metal coating layer forming method is not particularly limited, and known film forming methods (for example, sputtering) may be utilized as long as a desired metal coating layer is obtained.

Hereinafter, a specific producing step of the MgB₂ superconductive thin film wire material and the microscopic organization of the obtained MgB₂ thin film will be described.

### Long Metal Substrate Preparing Step

A long metal substrate preparing step is a step of preparing a long metal substrate 15 serving as a base of the MgB₂ superconductive thin film wire material. The long metal substrate 15 is made of any material without particular limitation as long as it has a length and mechanical properties (for example, 0.2% proof strength) according to utilization applications as a superconductive wire material, and heat resistance that withstands a heat treatment during the producing process of the superconductive wire material. For example, stainless steel, silicon steel, a Ni (nickel)-based superalloy, and a Cu (copper) alloy and the like can be preferably used. The long metal substrate 15 is desirably subjected to surface cleaning before use so as not to hinder the formation of a thin film in a subsequent step.

### MgB₂ Thin Film Forming Step

An MgB₂ thin film forming step is a step of forming an MgB₂ thin film on the long metal substrate 15 according to a vacuum process. The production method of the present invention has the greatest feature in the MgB₂ thin film forming step.

The present step is preferably performed by a co-evaporation method under a substrate temperature condition of 250° C. or higher and 300° C. or lower in a vacuum atmosphere, and more preferably performed under a substrate temperature condition of 280° C. or higher and 300° C. or lower. When the temperature of the long metal substrate 15 is lower than 250° C., the T_{c} of the formed MgB₂ thin film is apt to be lower than 30 K, so that good J_{c} properties in a 20 K magnetic field are not obtained. Meanwhile, when the temperature of the long metal substrate 15 exceeds 300° C., an Mg component having a high vapor pressure is apt to be scattered (re-evaporated), which causes a decreased production rate of an MgB₂ phase.

The present step is preferably controlled so as to contain a highly oxidative gas in a partial pressure range of 0.05% or more and 0.2% or less of an Mg vapor partial pressure as a vacuum atmosphere during deposition. When the partial pressure of the highly oxidative gas is less than 0.05% of the Mg vapor partial pressure, the production amount of the Mg oxide becomes insufficient, so that good J_{c} properties in a 20 K magnetic field are not obtained. Meanwhile, when the partial pressure of the highly oxidative gas exceeds 0.2% of the Mg vapor partial pressure, the production amount of the Mg oxide becomes excessive, which inhibits a superconductive current path, so that good J_{c} properties are not obtained.

As a specific example, when the Mg vapor partial pressure estimated from a substrate temperature and a film formation rate during deposition is 1×10⁻³ Pa to 1×10⁻² Pa, the partial pressure of the highly oxidative gas is preferably controlled in a range of 5×10⁻⁷ Pa to 2×10⁻⁵ Pa.

### Microscopic Organization of MgB₂ Thin Film

As a result of the MgB₂ thin film forming step, MgB₂ columnar crystal grains densely stand on the surface of the long metal substrate 15, and an MgB₂ thin film is obtained. The MgB₂ thin film has a microscopic organization in which an Mg oxide layer is formed in such a manner as to surround the MgB₂ columnar crystal grains in a grain boundary region of the MgB₂ columnar crystal grains. The formation of the Mg oxide layer in the grain boundary region of the MgB₂ columnar crystal grains is considered to provide a function effect (strengthening of magnetic flux pinning) of the precipitation of a non-superconductive phase and the suppression of the coarsening of the MgB₂ columnar crystal grains (increase in a grain boundary density in a plane parallel to the surface of the MgB₂ thin film).

In the present invention, the Mg oxide layer is produced at the same time as the production of the MgB₂ columnar crystal grains during the MgB₂ thin film forming step, whereby the Mg oxide layer is considered to be grown while forming a honeycomb-like shape. This crystal growth mechanism is not yet elucidated at this stage, but it is largely different from a process of introducing a magnetic flux pinning center into the grain boundary region by an element diffusion heat treatment as in PTL 1, and can be said to be a very interesting film forming process.

The average thickness of the Mg oxide layer is preferably 1 nm or more and less than 7 nm, more preferably 1 nm or more and 6 nm or less, and still more preferably from 1 nm or more and 5 nm or less. The average thickness of less than 1 nm of the Mg oxide layer makes it difficult to surround each MgB₂ columnar crystal grain, which causes insufficient suppression of the coarsening of the MgB₂ columnar crystal grains. Meanwhile, when the average thickness of the Mg oxide layer is 7 nm or more, the thickness of the non-superconductive phase is equal to or greater than the coherence length (7 nm) of MgB₂, so that a superconductive current flowing through the MgB₂ thin film is inhibited.

The total area ratio of the Mg oxide layer is preferably 2% or more and 20% or less, more preferably 2% or more and 15% or less, and still more preferably 2% or more and 10% or less. The total area ratio of less than 2% of the Mg oxide layer makes it difficult to surround each MgB₂ columnar crystal grain, which causes insufficient suppression of the coarsening of the MgB₂ columnar crystal grains. Meanwhile, when the total area ratio of the Mg oxide layer exceeds 20%, the ratio of the MgB₂ phase is decreased, so that good J_{c} properties are not obtained.

In a superconductive wire material for power application (for example, a superconductive electromagnet, a power cable), both high J_{c} properties and high electrical conduction properties are important. Accordingly, it is necessary to make the cross-sectional area of the conductor large. Therefore, in the case of the superconductive thin film wire material for power application, the film thickness of the MgB₂ thin film is preferably micrometers order (for example, 1 to 20 μm).

Even in the thin film produced by a vacuum process, the diameters of the crystal grains generally tend to be increased (that is, the crystal grain boundary density is decreased) as the film becomes thicker. Therefore, it is preferable that, when a thick MgB₂ thin film is formed (for example, when the film thickness exceeds 10 μm), as described in PTL 1, the MgB₂ thin film is repeatedly formed more than once to provide a laminated structure including a plurality of MgB₂ thin films.

From the viewpoint of the grain boundary density of the MgB₂ phase, the average particle diameter of the MgB₂ columnar crystal grains (for example, the average particle diameter on the surface of the MgB₂ thin film) is preferably 25 nm or more and 300 nm or less, more preferably 30 nm or more and 250 nm or less, and still more preferably 40 nm or more and 200 nm or less. When the average particle diameter is less than 25 nm, the crystallinity of the MgB₂ phase is apt to be insufficient, so that good J_{c} properties are not obtained. Meanwhile, the average particle diameter exceeding 300 nm makes it difficult to secure J_{c} properties equal to or greater than those of a conventional MgB₂ superconductive thin film wire material.

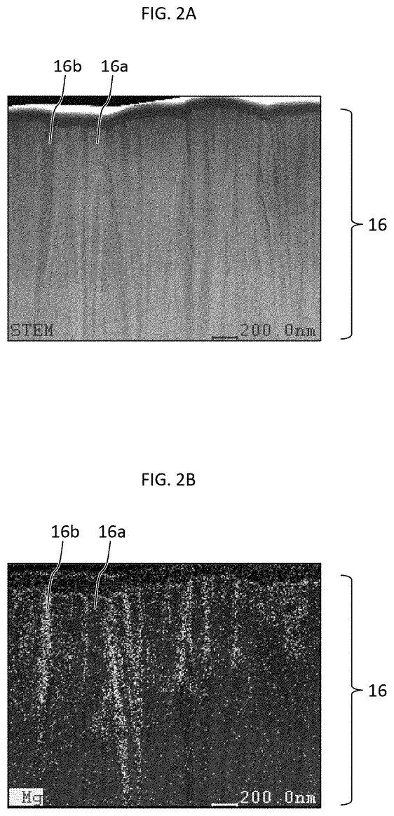

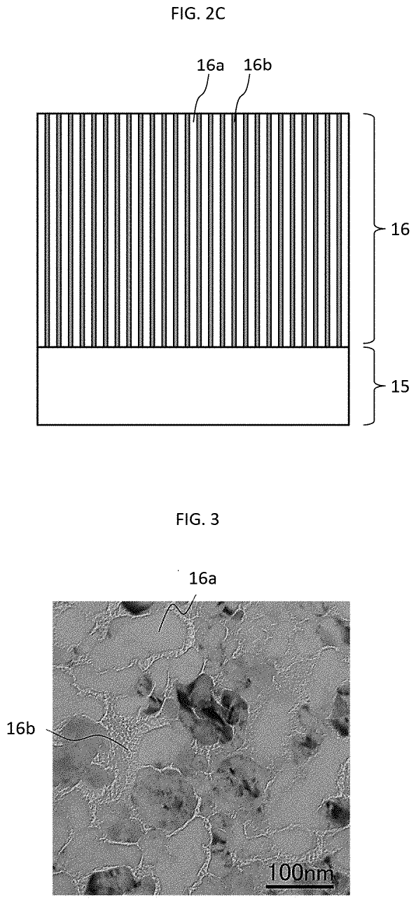

FIG. 2A is an annular dark field (ADF) image of a scanning transmission electron microscope (STEM) observation showing an example of a microscopic organization of a cross section of an MgB₂ thin film (film thickness: 5 m) (a cross section perpendicular to the surface of the MgB₂ thin film). FIG. 2B is a combination of Mg element mapping and O element mapping in FIG. 2A. In FIG. 2B, a white spot is a portion where an O atom concentration is high. FIG. 2C is a schematic cross-sectional view of an MgB₂ thin film based on FIGS. 2A and 2B.

As shown in FIGS. 2A to 2C, in an MgB₂ thin film 16 of the present invention, a large number of MgB₂ columnar crystal grains 16a densely stand on the surface of the long metal substrate 15. As a result, the grain boundary of the MgB₂ columnar crystal grains 16a is confirmed to be present at a high density. An Mg oxide layer 16b (a layer considered to be substantially MgO) is confirmed to be formed in the grain boundary region of the MgB₂ columnar crystal grains 16a.

FIG. 3 is a transmission electron microscope (TEM) observation image showing an example of a microscopic organization of a horizontal cross section of an MgB₂ thin film (film thickness: 5 μm) (a cross section parallel to the surface of the MgB₂ thin film). As shown in FIG. 3, the Mg oxide layer 16b is confirmed to be formed in such a manner as to surround the MgB₂ columnar crystal grains 16a in the grain boundary region of the MgB₂ columnar crystal grains 16a.

In FIG. 3, the average thickness and total area ratio of the Mg oxide layer 16b and the average particle diameter of the MgB₂ columnar crystal grains 16a are measured using image analysis software (ImageJ, public domain software). The average particle diameter is 5 nm; the total area ratio is 10%; and the average particle diameter is 100 nm. It is considered that the average thickness (5 nm) of the Mg oxide layer 16b is smaller than the coherence length (7 nm) of MgB₂, so that the superconductive current flowing through the MgB₂ thin film is not inhibited.

As shown in FIG. 3, regions where the thickness of the Mg oxide layer 16b is 7 nm or more are also observed in some places, but the region where the thickness is 7 nm or more, covering the entire circumference of the MgB₂ columnar crystal grains 16a is not observed. From this, the region where the thickness is 7 nm or more is considered to have substantially no adverse effect on the J_{c} properties.

### Metal Coating Layer Forming Step

A metal coating layer forming step is a step of forming a metal coating layer on the surface of the MgB₂ thin film 16 by a vacuum process. The present step is not an essential step, but it is preferably performed from the viewpoint of protecting the MgB₂ thin film 16 and stabilizing the superconductive wire material.

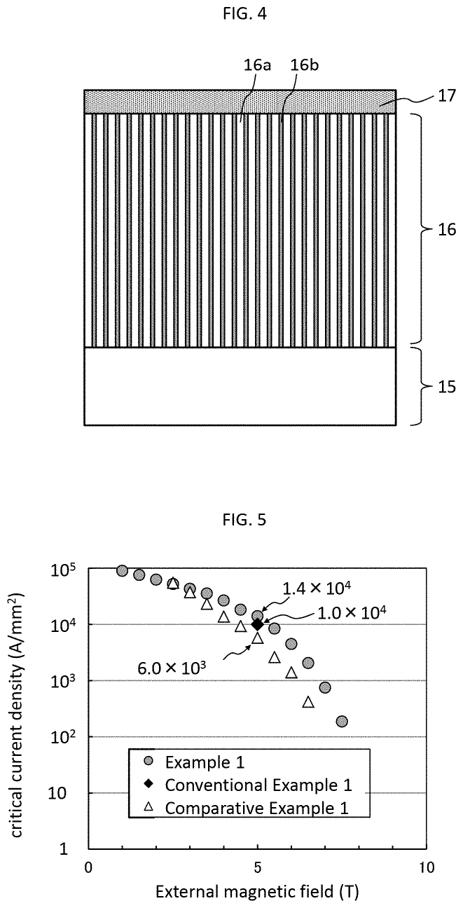

FIG. 4 is a schematic view showing an example of a microscopic organization of a cross section of an MgB₂ superconductive thin film wire material after a metal coating layer forming step. As shown in FIG. 4, a metal coating layer is formed on the surface of the MgB₂ thin film 16. The thickness of the metal coating layer 17 is appropriately determined based on the stabilization design of the superconductive wire material, and is set to be equal to or greater than that of the MgB₂ thin film 16, for example.

As the material of the metal coating layer 17, a low electrical resistance metal (for example, oxygen-free copper or pure aluminum) or a high corrosion resistance metal (for example, chromium or nickel) is preferably used. The metal coating layer 17 may have a laminated structure including a low electrical resistance metal layer and a high corrosion resistance metal layer as required.

The MgB₂ superconductive thin film wire material according to the present invention is completed through the above steps. The production method according to the present invention provides the precipitation of the non-superconductive phase that leads to strengthening of magnetic flux pinning only in the MgB₂ thin film forming step and the suppression of the coarsening of the MgB₂ columnar crystal grains, whereby the production method does not require the steps (transition metal element layer forming step, diffusion heat treatment step) described in PTL 1. From this, it can be said that the production method of the present invention and the MgB₂ superconductive thin film wire material obtained by the method can provide a lower cost than that of the conventional technique.

### EXAMPLES

Hereinafter, specific examples of the present invention will be described in more detail by way of Examples.

### Experiment 1

### Production of Example 1 Series

An MgB₂ superconductive thin film wire material of Example 1 series was produced by the production method described above. First, a Ni-based superalloy tape was used as a long metal substrate 15, and an MgB₂ thin film 16 (thickness: 10 μm) was formed on the long metal substrate 15 by an electron beam co-deposition method (substrate temperature: 280° C., Mg vapor partial pressure: 5×10⁻³ Pa, water vapor partial pressure: 5×10⁻⁶ Pa) as shown in FIG. 1. Next, a Cr layer (thickness: 10 μm) was formed as a metal coating layer 17 on the surface of the MgB₂ thin film 16. The obtained sample was used as a sample for evaluating superconductive properties.

Samples including the MgB₂ thin film 16 having thicknesses of 1 μm, 5 μm, and 10 μm and no metal coating layer 17 were separately prepared for observing a microscopic organization.

### Production of Comparative Example 1 Series

An MgB₂ superconductive thin film wire material of Comparative Example 1 series was produced in the same manner as in Example 1 series except that water vapor was not introduced into a vacuum atmosphere in an MgB₂ thin film forming step.

### Preparation of Conventional Example 1 Series

In accordance with the description of PTL 1, an MgB₂ superconductive thin film wire material of Conventional Example 1 series was produced.

### Experiment 2

### Observation of Microscopic Organization

The microscopic organization of each sample was observed using a transmission electron microscope (TEM), and the average particle diameter of MgB₂ columnar crystal grains was measured using image analysis software. FIG. 3A shows the observation results of a sample of Example 1 series having an MgB₂ thin film thickness of 5 μm.

In Example 1 series, as the thickness of the MgB₂ thin film was increased to 1 μm, 5 μm, and 10 μm, the average particle diameter of the MgB₂ columnar crystal grains was increased to 30 nm, 100 nm, and 200 nm. Meanwhile, in Comparative Example 1 series and Conventional Example 1 series, as the thickness of the MgB₂ thin film was increased to 1 μm, 5 μm, and 10 μm, the average particle diameter of the MgB₂ columnar crystal grains was increased to 50 nm, 150 nm, and 300 nm.

From the observation of these microscopic organizations, Example 1 series according to the present invention were confirmed to have a smaller average particle diameter of MgB₂ columnar crystal grains than that of each of Comparative Example 1 series and Conventional Example 1 series. This is considered to be because the formation of the Mg oxide layer, which is a feature of the present invention, suppresses the coarsening of the MgB₂ columnar crystal grains.

### Experiment 3

### Measurement of Superconductive Properties

By using the samples for evaluating superconductive properties of Example 1, Comparative Example 1, and Conventional Example 1 (MgB₂ thin film thickness: 10 μm), a critical temperature (T_{c}) and J_{c} properties in a magnetic field (J_{c}-B properties) were measured. T_{c} measurement was performed with a superconductive quantum interference device (SQUID). As a result of the T_{c} measurement, all samples were confirmed to show T_{c} of 30 K or higher. In other words, it was confirmed that the production method of the present invention does not adversely affect the T_{c} of the MgB₂ superconductive thin film wire material.

The J_{c}-B measurement was performed by perpendicularly applying a magnetic field to the surface of the thin film according to a normal four-terminal energization method. The results are shown in FIG. 5. FIG. 5 is a graph showing an example of the relationship between a critical current density J_{c} and an external magnetic field B under a temperature environment of 20 K in the MgB₂ superconductive thin film wire materials of Example 1, Comparative Example 1, and Conventional Example 1.

As shown in FIG. 5, it is found that, when Example 1 and Comparative Example 1 are compared with each other, Example 1 has more excellent J_{c} properties than those of Comparative Example 1 on a high magnetic field side of an external magnetic field of 3 T or higher. This strongly suggests that a magnetic flux pinning center other than the grain boundary is introduced by the formation of the Mg oxide layer.

It is confirmed that, when Example 1 and Comparative Example 1 are compared with each other at an external magnetic field of 5 T, Comparative Example 1 has J_{c} properties of 6.0×10³ A/mm² and Conventional Example 1 has J_{c} properties of 1.0×10⁴ A/mm², whereas Example 1 has J_{c} properties of 1.4×10⁴ A/mm², and exhibits extremely good J_{c} properties. This is considered to be due to the contribution of the suppression of the coarsening of the MgB₂ columnar crystal grains (the refinement of the MgB₂ columnar crystal grains) provided by the formation of the Mg oxide layer.

From these results, it was demonstrated that the MgB₂ superconductive thin film wire material according to the present invention has superconductive properties equal to or greater than those of the conventional technique.

### Experiment 4

### Production of Examples 2 to 3 and Measurement of Superconductive Properties

An MgB₂ superconductive thin film wire material of Example 2 (MgB₂ thin film thickness: 10 μm) was produced in the same manner as in Example 1 series except that a highly oxidative gas introduced into a vacuum atmosphere in an MgB₂ thin film forming step was changed from water vapor to ozone. An MgB₂ superconductive thin film wire material (MgB₂ thin film thickness: 10 μm) of Example 3 was produced in the same manner as in Example 1 series except that the highly oxidative gas was changed from water vapor to a hydrogen peroxide gas.

The obtained samples of Examples 2 and 3 were measured for superconductive properties. As a result, it was confirmed that Examples 2 to 3 exhibit the same superconductive properties as those of Example 1 (Tc≥30 K, J_{c}≈1.4×10⁴ A/mm² (under environments of 20 K, 5 T).

The above-described embodiments and Examples are described in order to facilitate understanding of the present invention, and the present invention is not limited to only the specific configurations described. For example, a part of the configuration of an embodiment is replaceable with the configuration of the common technical knowledge of those skilled in the art, and the configuration of the common technical knowledge of those skilled in the art can be added to the configuration of the embodiment. That is, the present invention makes it possible to delete some of the configurations of embodiments and Examples in the present specification, replace some of the configurations by the other configurations, and add the other configurations to some of the configurations without departing from the technical concept of the invention.

### REFERENCE SIGNS LIST

100 producing apparatus
10 MgB₂ thin film forming mechanism
20 atmosphere controlling mechanism
11 electron gun array
11a electron beam
12 linear type raw material evaporation source
12a Mg evaporation source
12b B evaporation source
13 raw material vapor
14 reel
15 long metal substrate
16 MgB₂ thin film
16a MgB₂ columnar crystal grains
16b Mg oxide layer
17 metal coating layer
21 vacuum chamber
22 pump
23 tank
24 variable leak valve

1. An MgB₂ superconductive thin film wire material comprising: a long metal substrate; and an MgB₂ thin film formed on the long metal substrate, wherein:
the MgB₂ thin film has a critical temperature of 30 K or higher, and has a microscopic organization in which MgB₂ columnar crystal grains densely stand on a surface of the long metal substrate, and an Mg oxide layer is formed in such a manner as to surround the MgB₂ columnar crystal grains in a grain boundary region of the MgB₂ columnar crystal grains.

2. The MgB₂ superconductive thin film wire material according to claim 1, wherein the Mg oxide layer has an average thickness of 1 nm or more and less than 7 nm.

3. The MgB₂ superconductive thin film wire material according to claim 1, wherein a total area ratio of the Mg oxide layer in a plane parallel to a surface of the MgB₂ thin film is 2% or more and 20% or less.

4. The MgB₂ superconductive thin film wire material according to claim 1, wherein the MgB₂ columnar crystal grains on a surface of the MgB₂ thin film have an average particle diameter of 25 nm or more and 250 nm or less.

5. The MgB₂ superconductive thin film wire material according to claim 1, wherein the MgB₂ thin film has a thickness of 1 μm or more and 20 μm or less.

6. The MgB₂ superconductive thin film wire material according to claim 1, further comprising a metal coating layer formed on a surface of the MgB₂ thin film.

7. The MgB₂ superconductive thin film wire material according to claim 6, wherein the metal coating layer includes a layer made of Cr or Ni.

8. A production method for an MgB₂ superconductive thin film wire material, the MgB₂ superconductive thin film wire material including: a long metal substrate; and an MgB₂ thin film formed on the long metal substrate, wherein:
the MgB₂ thin film has a critical temperature of 30 K or higher, and has a microscopic organization in which MgB₂ columnar crystal grains densely stand on a surface of the long metal substrate and an Mg oxide layer is formed in such a manner as to surround the MgB₂ columnar crystal grains in a grain boundary region of the MgB₂ columnar crystal grains,
the method comprises an MgB₂ thin film forming step of forming the MgB₂ thin film on the long metal substrate by a co-evaporation method under a predetermined temperature condition in a predetermined vacuum atmosphere;
the predetermined vacuum atmosphere is controlled so as to contain a highly oxidative gas in a partial pressure range of 0.05% or more and 0.2% or less of an Mg vapor partial pressure during deposition; and
in the predetermined temperature condition, a temperature of the long metal substrate is controlled to 250° C. or higher and 300° C. or lower.

9. The production method for an MgB₂ superconductive thin film wire material according to claim 8, wherein the highly oxidative gas is one or more of water vapor, ozone, and hydrogen peroxide.

10. The production method for an MgB₂ superconductive thin film wire material according to claim 8, wherein a partial pressure of the highly oxidative gas is 5×10⁻⁷ Pa or more and 2×10⁻⁵ Pa or less.

11. The production method for an MgB₂ superconductive thin film wire material according to claim 8, further comprising a metal coating layer forming step of further forming a metal coating layer on a surface of the MgB₂ thin film after the MgB₂ thin film forming step.

12. The production method for an MgB₂ superconductive thin film wire material according to claim 11, wherein the metal coating layer includes a layer made of Cr or Ni.
